(19) United States
(12) Patent Application Publication
(10) Pub. No.: US 2002/0043466 A1
(43) Pub. Date: Apr. 18, 2002

(54) Method and apparatus for patching electrochemically deposited layers using electroless deposited materials

(75) Inventors: Yezdi N. Dordi, Palo Alto, CA (US); Peter W. Hey, Sunnyvale, CA (US)

Correspondence Address: PATENT COUNSEL, APPLIED MATERIALS, INC., Legal Affairs Department, P.O. BOX 450A, Santa Clara, CA, 95052, US

(73) Assignee: APPLIED MATERIALS, INC.

(21) Appl. No.: 09/900,710

(22) Filed: Jul. 6, 2001

Related U.S. Application Data
(63) Continuation-in-part of application No. 09/350,877, filed on Jul. 9, 1999.
(60) Provisional application No. 60/217,598, filed on Jul. 11, 2000.

(51) Int. Cl. C25D 5/02; H01L 21/288; H01L 21/445; C25D 5/10; C23C 28/02; C25D 5/50

(52) U.S. Cl. 205/123; 205/186; 205/224; 205/170; 427/404

(57) ABSTRACT

Methods and apparatus for forming a conformal conductive layer on a substrate for an electroplating process are provided. In one aspect, a method is provided for processing a substrate including depositing a conductive barrier layer on the substrate, and then depositing a nucleation layer on the conductive barrier layer. The nucleation layer is deposited by depositing a first conductive material on the substrate and then depositing a second conductive material on the first conductive material by an electroless deposition process. The second conductive material may comprise nickel, tin, or combinations thereof. The substrate may then be further processed by electroplating a third conductive material on the second conductive material and/or annealing the substrate.

### CROSS-REFERENCE TO RELATED APPLICATIONS

This application claims benefit of U.S. provisional patent application serial No. 60/217,598, filed Jul. 11, 2000, which is herein incorporated by reference, and is a continuation-in-part of co-pending U.S. patent application Ser. No. 09/350,877 [AMAT/3698], filed on Jul. 9, 1999, which is herein incorporated by reference.

### BACKGROUND OF THE INVENTION

1. Field of the Invention

The present invention generally relates to an apparatus and process for deposition of a conductive layer onto a substrate.

2. Background of the Related Art

Reliably producing sub-half micron and smaller features is one of the key technologies for the next generation of very large scale integration (VLSI) and ultra large-scale integration (ULSI) of semiconductor devices. However, as the fringes of circuit technology are pressed, the shrinking dimensions of interconnects in VLSI and ULSI technology has placed additional demands on the processing capabilities. The multilevel interconnects that lie at the heart of this technology require precise processing of high aspect ratio features, such as vias and other interconnects. Reliable formation of these interconnects is very important to VLSI and ULSI success and to the continued effort to increase circuit density and quality of individual substrates and die.

As circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Many traditional deposition processes have difficulty filling sub-micron structures where the aspect ratio exceeds 4:1, and particularly where the aspect ratio exceeds 10:1. Therefore, there is a great amount of ongoing effort being directed at the formation of substantially void-free, sub-micron features having high aspect ratios.

Currently, copper and its alloys have become the metals of choice for sub-quarter-micron interconnect technology because copper has a lower resistivity than aluminum, (1.7 μΩ-cm compared to 3.1 μΩ-cm for aluminum), a higher current carrying capacity, and significantly higher electromigration resistance. These characteristics are important for supporting the higher current densities experienced at high levels of integration and increased device speed. Further, copper has a good thermal conductivity and is available in a highly pure state.

Electroplating is one process being used to deposit copper and in some applications to fill high aspect ratio features on substrates. Electroplating processes typically require the electrically conductive nucleation, or seed, layer, to be thin and conformally deposited on the substrate to provide a surface on the substrate to adequately initiate the electroplating process. The seed layer typically includes a conductive metal, such as copper, and is conventionally deposited on the substrate using physical vapor deposition (PVD) or chemical vapor deposition (CVD) techniques. It has been found that conformal deposition of the seed layer results in good electroplating of the substrate. However, as feature sizes decrease, the ability to deposit conformal or uniform seed layers can be compromised.

Seed layers that are not deposited uniformly on the substrate can result in layer agglomeration or create a discontinuous layer over portions of the substrate and in the features formed on the substrate. Non-uniform deposition and agglomeration of the seed layer can result in a current that is not evenly distributed over the surface of the seed layer and may result in non-uniform deposition of subsequent electrochemical deposited layers on the substrate. The non-uniform deposition of subsequent layers has been observed to be detrimental to circuit uniformity, conductivity, and reliability.

For example, non-uniform or agglomerated layers may cause subsequently deposited material to deposit at a higher rate on the sides than the bottom of a feature, which may result in “bridging” over substrate feature openings. Bridging of features may result in void formation and other discontinuities within the substrate features that have been observed to detrimentally affect the performance of a semi-conductor device, such as circuit uniformity, conductivity, and reliability, and may even lead to device failure. Furthermore, the non-uniformity and agglomeration of the seed layer may also reduce the effective adhesion of conductive material, such as copper, to the substrate and reduces the ability of subsequent layers to adequately bond to the conductive material.

Therefore, there is a need for a method for deposition of a conformal layer for electrochemical deposition processes.

### SUMMARY OF THE INVENTION

The invention generally provides a method and an apparatus for forming a conformal conductive layer on a substrate for an electroplating process. In one aspect, a method is provided for processing a substrate, comprising depositing a conductive barrier layer on the substrate, depositing a first conductive material on the substrate, and then depositing a second conductive material on the first conductive material by an electroless deposition process to fill discontinuities formed in the seed layer.

In another aspect, the invention provides a method for processing a substrate including depositing a barrier layer on the substrate, depositing a seed layer of a first conductive material on the barrier layer by a physical vapor deposition process or a chemical vapor deposition process, exposing the substrate to an electroless deposition process to deposit a second conductive material selected from the group of nickel, tin, and combinations thereof, on the seed layer to fill discontinuities formed in the seed layer, and depositing a third conductive material on the second conductive material by an electroplating process.

In another aspect, a method is provided for patching an electroplating seed layer including depositing a barrier layer on the substrate, depositing a copper seed layer on the barrier layer by a physical vapor deposition process, wherein the copper seed layer is discontinuous, depositing a nickel patching layer on the copper seed layer by an electroless deposition process, depositing a copper layer on the nickel patching layer by an electroplating process, and annealing the substrate after electroplating the third conductive material.

In another aspect, a method is provided for depositing a conductive layer in a feature on a substrate including depositing a first conductive layer in a feature on the substrate, depositing a second conductive layer in the feature by an electroless deposition process, and electroplating a third conductive layer in the feature to at least partially fill the feature.

### BRIEF DESCRIPTION OF THE DRAWINGS

A more particular description of certain aspects of the invention, briefly summarized above, may be had by reference to the appended drawings that illustrate the embodiments thereof.

It is to be noted, however, that the appended drawings illustrate only typical embodiments of this invention, and therefore, are not to be considered limiting of its scope, for the invention may admit to other equally effective embodiments.

FIG. 1 is a flow chart illustrating steps undertaken in depositing conductive layers according to one embodiment of the invention;

FIG. 2 is a schematic side view of an ionized metal plasma (IMP) physical vapor deposition chamber;

FIG. 3 is a cross-sectional view of a chemical vapor deposition (CVD) processing chamber;

FIG. 4 is a schematic perspective view of one electroless deposition process (EDP) cell 210;

FIG. 5 is a cross sectional view of an electroplating process cell;

FIG. 6 is a schematic top view of an electroplating system platform; and

FIGS. 7A-7F are schematic diagrams of one embodiment of a process for forming a feature on a substrate.

### DETAILED DESCRIPTION OF THE PREFERRED EMBODIMENT

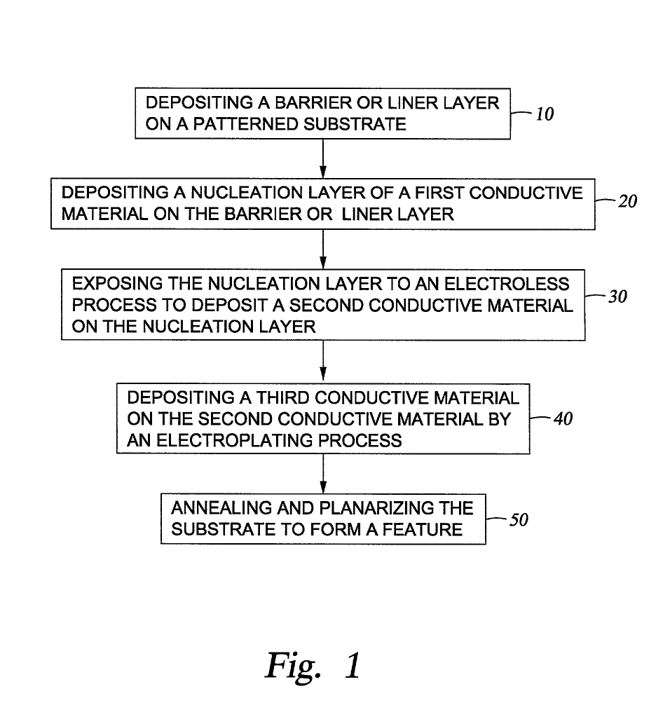

FIG. 1 is a flow chart illustrating steps undertaken in processing a substrate according to one embodiment of the invention described herein. A patterned substrate is formed by depositing a dielectric layer on the substrate, depositing and patterning a photoresist material on the dielectric layer, and then etching apertures in the dielectric material according to the patterns formed in the photoresist material. After etching the dielectric layer, a barrier (and/or liner layer) is deposited on the patterned substrate and in the apertures formed therein at step 10.

A nucleation layer is formed on the substrate by depositing a first conductive material on the barrier or liner layer at step 20. A nucleation layer is broadly defined herein as continuously or discontinuously deposited material used to promote or facilitate growth of subsequently deposited layers on a substrate surface and to enhance interlayer adhesion of deposited layers. The nucleation layer may be referred to as a seed layer.

The first conductive material includes a material selected from the group of copper, nickel, tungsten, and combinations thereof. The first conductive material may also include alloys of copper, nickel, tungsten, or combinations thereof. The first conductive material may further include a doping material selected from a group of phosphorus, boron, indium, tin, beryllium or combinations thereof. The percentage by weight of the doping material is between about 0.01% by weight (wt. %) and about 15 wt. % of the nucleation layer. The dopant material preferably includes between about 0.01 wt. % and about 0.5 wt. % of the nucleation layer. The nucleation layer can be deposited by physical vapor deposition (PVD) techniques, such as ionized metal plasma physical vapor deposition (IMP-PVD), and collimated or long throw sputtering. Alternatively, the nucleation layer can be deposited by chemical vapor deposition (CVD) techniques.

A second conductive material is then deposited on the nucleation layer by exposing the nucleation layer to an electroless deposition process at step 30. The second conductive material performs as a patching layer to minimize the effect of discontinuities and agglomerated material in the nucleation layer. The patching layer is broadly defined herein as deposited material used to complete the formation of continuous layers and to minimize the effect of agglomerated material on subsequently deposited layers. The patching layer may be deposited continuously or discontinuously on the nucleation layer. The second conductive material typically includes materials that promote or facilitate growth of subsequently deposited layers on a substrate surface. As such, the deposited patching material layer may be further described as forming a portion of the nucleation layer

The second conductive material includes a material selected from the group of nickel, tin, and combinations thereof. The second conductive material may also include alloys of nickel, tin, or combinations thereof. The second conductive material may further include a dopant material of phosphorus, boron, and combinations thereof, with a dopant concentration between about 0.01 wt. % and about 15 wt. % of the patching layer, to improve electromigration properties and enhance the formation of a conformal layer.

A third conductive material is then deposited by electroplating techniques over the first and/or second conductive materials of the nucleation layer at step 40. For example, the third conductive material is conformally deposited on the first and second conductive material if the second conductive material is discontinuously deposited, and conformally deposited on the second conductive material if the second conductive material is continuously deposited. The third conductive material is typically deposited to fill apertures formed on the substrates to produce a conductive feature.

The third conductive material includes a material selected from the group of copper, nickel, and combinations thereof. The third conductive material may also include alloys of copper, nickel, or combinations thereof. The third conductive material may further include between about 0.01 wt. % and about 15 wt. % of a doping material selected from a group of phosphorus, boron, indium, tin, beryllium or combinations thereof. The dopant material may include between about 0.01 wt. % and about 0.5 wt. % of the third conductive material.

After deposition of the third conductive material, the aperture may then be annealed and/or planarized at step 50 by a chemical mechanical polishing process to form the feature.

One embodiment of the invention will now be described. While the following description uses nickel as a patching material on a copper nucleation layer for a copper electroplating fill of features, other materials for patching metal layers, including tin, doped nickel, doped tin, nickel-tin alloys, and combinations thereof, are also contemplated by the invention for patching nucleation layers and enhancing nucleation of subsequently electrochemically deposited materials.

Deposition of the Barrier or Liner layer on the Patterned Substrate.

A barrier and/or liner layer can be deposited prior to the deposition of the nucleation layer at step 10. Generally, liner layers promote interlayer adhesion between metal layers or between dielectric materials and subsequently deposited materials to the underlying material and barrier layers prevent or inhibit interlayer diffusion of the nucleation layer and subsequently deposited materials into the underlying substrate or dielectric layers.

Examples of liner and/or barrier layer materials used with the invention described herein include refractory metals and nitrides of refractory metals such as tantalum (Ta), tantalum nitride (TaNₓ), titanium (Ti), titanium nitride (TiNₓ), tungsten (W), tungsten nitride (WNₓ), and combinations thereof. Other suitable barrier and/or liner layers include niobium (Nb), aluminum silicates, titanium (TiN), titanium nitride (TiN), PVD Ti/N₂-stuffed, doped silicon, aluminum, and aluminum oxides, ternary compounds, such as TiSiN, titanium silicon nitride, WSiN, tungsten silicon nitride among others, or a combination of these layers. Liner and/or barrier materials including tantalum (Ta) and tantalum nitride (TaN), which may be deposited individually or sequentially, are preferably used with copper or doped copper metal layers.

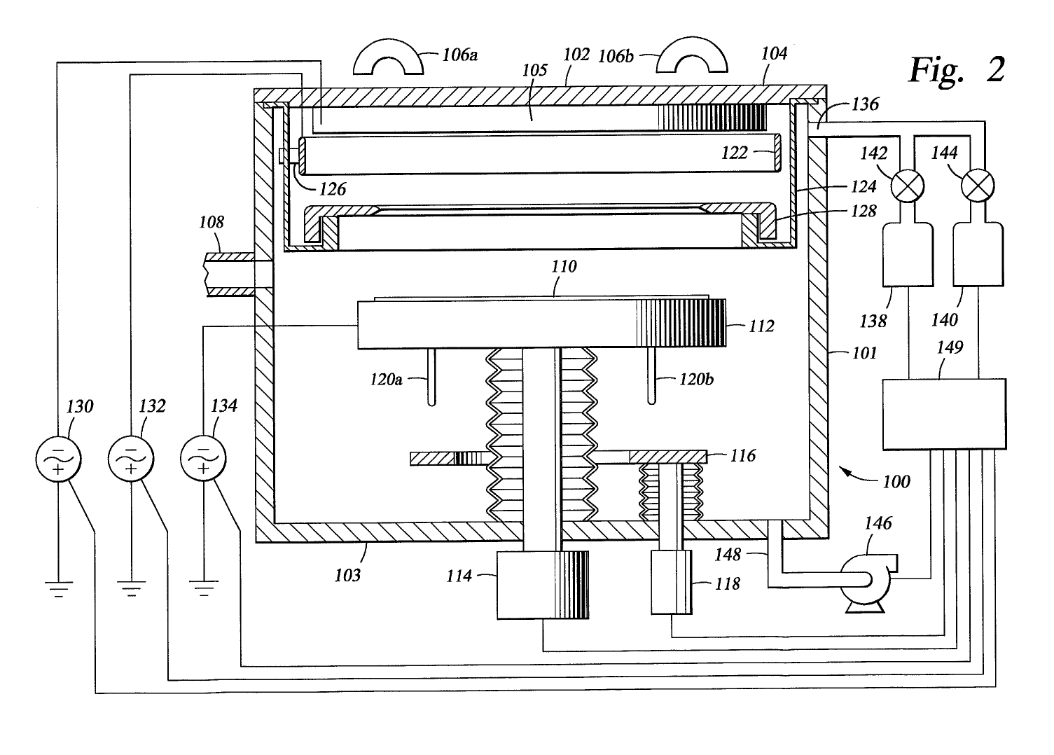

The barrier and/or liner layer may be deposited by chemical vapor deposition techniques and physical vapor deposition techniques, such as ionized metal plasma physical vapor deposition (IMP PVD) and collimated or long throw sputtering. In one embodiment, an IMP PVD process deposits a barrier layer. The deposition of the barrier and/or liner layer will now be described in reference to an ionized metal plasma physical vapor deposition (IMP-PVD) chamber as shown in FIG. 2.

FIG. 2 is a schematic cross-sectional view of one embodiment of an ionized metal plasma physical vapor deposition (IMP-PVD) chamber 100, capable of generating a relatively high density plasma, i.e., one with a capability to ionize a significant fraction of both the process gas (typically argon) and the sputtered target material to deposit a layer of material on a substrate. A sputtering chamber, known as an IMP Vectra™ chamber, is available from Applied Materials, Inc. of Santa Clara, Calif. The IMP-PVD chamber 100 can be integrated into an Endura™ platform, also available from Applied Materials, Inc.

The IMP-PVD process provides higher density plasma than standard PVD that causes the sputtered target material to become ionized as the sputtered material passes therethrough. The ionization enables the sputtered material to be attracted in a substantially perpendicular direction to a biased substrate surface and to deposit a layer of material in high aspect ratio features. The high density plasma is supported by a coil 122 internal to the chamber through which AC current is passed. The chamber 100 includes sidewalls 101, lid 102, and bottom 103. The lid 102 includes a target backing plate 104 that supports a target 105 of the material to be deposited. The target 105 is made of the conductive material useful as a barrier or liner layer or a nucleation layer. In one embodiment, the target 105 includes tantalum for use in a barrier/liner layer deposition process, and the target 105 includes copper in a copper nucleation layer deposition process.

An opening 108 in the chamber 100 provides access for a robot (not shown) to deliver and retrieve substrates 110 to and from the chamber 100. A substrate support 112 supports the substrate 110 in the chamber and is typically grounded. The substrate support 112 is mounted on a lift motor 114 that raises and lowers the substrate support 112 and a substrate 110 disposed thereon. A lift plate 116 connected to a lift motor 118 is mounted in the chamber 100 and raises and lowers pins 120a, 120b mounted in the substrate support 112. The pins 120a, 120b raise and lower the substrate 110 from and to the surface of the substrate support 112. A coil 122 is mounted between the substrate support 112 and the target 105 and provides inductively-coupled magnetic fields in the chamber 100 to assist in generating and maintaining a plasma between the target 105 and substrate 110. The coil 122 is sputtered due to its location between the target and the substrate 110 and preferably is made of similar constituents as the target 105. For instance, the coil 122 could be made of tantalum and the target 105 could be made of tantalum for deposition of a tantalum or tantalum nitride layer. Power supplied to the coil 122 densifies the plasma that ionizes the sputtered material. The ionized material is then directed toward the substrate 110 and deposited thereon.

A shield 124 is disposed in the chamber 100 to shield the chamber sidewalls 101 from the sputtered material. The shield 124 also supports the coil 122 by coil supports 126. The coil supports 126 electrically insulate the coil 122 from the shield 124 and the chamber 100 and can be made of similar material as the coil. The clamp ring 128 is mounted between the coil 122 and the substrate support 112 and shields an outer edge and backside of the substrate from sputtered materials when the substrate 110 is raised into a processing position to engage the lower portion of the clamp ring 128. In some chamber configurations, the shield 124 supports the clamp ring 128 when the substrate 110 is lowered below the shield 124 to enable substrate transfer.

Three power supplies are used in this type of sputtering chamber. In one embodiment, a power supply 130 delivers DC power to the target 105 to cause the processing gas to form a plasma, although RF power can be used. Magnets 106a, 106b disposed behind the target backing plate 104 increase the density of electrons adjacent to the target 105, thus increasing ionization at the target to increase the sputtering efficiency. The magnets 106a, 106b generate magnetic field lines generally parallel to the face of the target, around which electrons are trapped in spinning orbits to increase the likelihood of a collision with, and ionization of, a gas atom for sputtering. In one embodiment, a power supply 132 supplies RF power to the coil 122 to couple with and increase the density of the plasma. In one embodiment, a power supply 134 delivers DC power supply to the substrate support 112 to bias the substrate support 112 with respect to the plasma and provides directional attraction (or repulsion) of the ionized sputtered material toward the substrate 110.

Processing gas, such as an inert gas of argon or helium for metal layer deposition, and which may include a reactive gas, such as nitrogen for a metal nitride layer deposition, is supplied to the chamber 100 through a gas inlet 136 from gas sources 138, 140 as metered by respective mass flow controllers 142, 144. A vacuum pump 146 is connected to the chamber 100 at an exhaust port 148 to exhaust the chamber 100 and maintain the desired pressure in the chamber 100. A controller 149 generally controls the functions of the power supplies, lift motors, mass flow controllers for gas injection, vacuum pump, and other associated chamber components and functions.

An exemplary process regime for the IMP deposition of tantalum layer in an ion metal plasma (IMP) chamber as shown in FIG. 2 is as follows. An inert gas, such as helium or argon, is introduced into the chamber at a rate sufficient to produce a chamber pressure between about 0.5 milliTorr and about 100 milliTorr.

A plasma is generated by supplying a RF source power to the coil at a power density between about 0.5 W/cm² and about 77 W/cm², or a power level of between about 200 watts and about 24000 watts for a 200 mm substrate. Alternatively, RF source power is supplied to the coil at a power density between about 3 W/cm² and about 10 W/cm², or a power level of between 1000 watts and about 3000 watts for a 200 mm substrate.

The target in the IMP-PVD chamber is DC-biased at a power density between about 0.5 W/cm² and about 77 W/cm², or a power level of between about 200 watts and about 24000 watts for a 200 mm substrate, and between about 20 Volts (V) and about 2400 V to sputter the target.

Power is supplied to the support member at a power level between about 0 watts (W) and about 500 watts (W) for a 200 mm substrate when the power to the target and the coil are between about 1000W and about 3000W. Alternatively, the substrate support is biased at a power density between about 0.5 W/cm² and about 1.6 W/cm² during the deposition process.

The substrate is maintained at a temperature of less than about 400° C. A substrate temperature between about 10° C. and about 300° C. is preferably used during the deposition process.

Depositing a nitride material, such as tantalum nitride, includes sputtering the target in a nitrating atmosphere under the above described processing parameters. A nitrating environment is provided by flowing nitrogen, and typically, an inert gas into the processing chamber at a flow rate sufficient to produce a chamber pressure between about 0.5 milliTorr and about 100 milliTorr and form a metal nitride material.

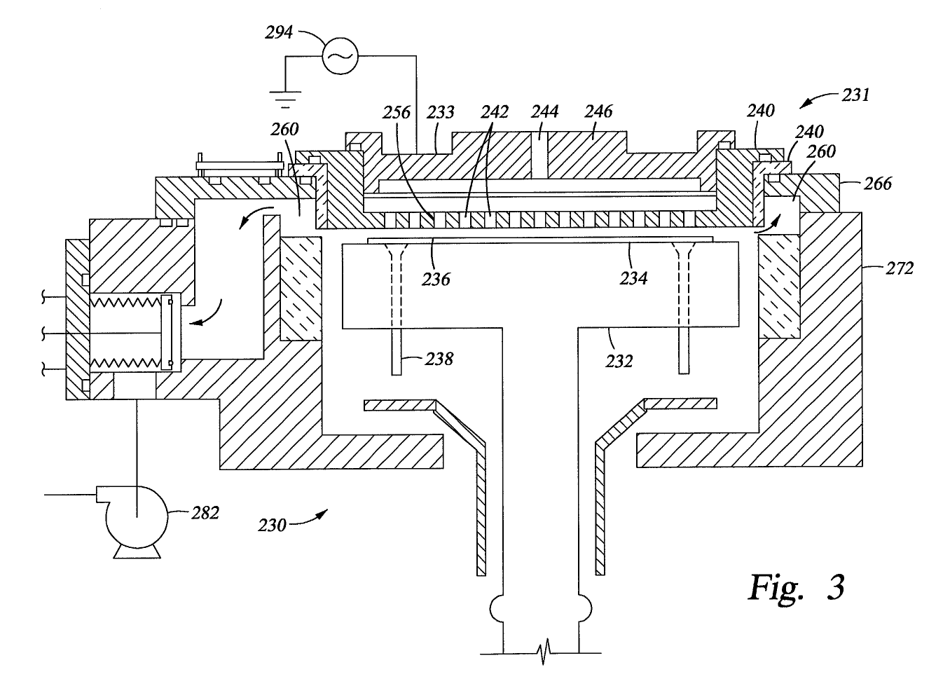

In an alternative embodiment, the barrier or liner material may be deposited in a chemical vapor deposition chamber. One embodiment of an exemplary chemical vapor deposition chamber is a CVD TxZ™ Chamber, commercially available from Applied Materials, Inc., of Santa Clara, Calif., is schematically shown in FIG. 3. The CVD TXZ™ Chamber is capable of depositing conductive materials from chemical precursors with thermal or plasma enhanced deposition processes. The CVD chamber 230 includes a pedestal 232 having a supporting surface 234 on which a substrate 236 is supported for chemical vapor deposition of a desired material thereon. Positioning the substrate 236 on the supporting surface is facilitated by vertically movable lift pins 238.

A gas delivery assembly 231 is disposed on a lid rim 266 at an upper end of the chamber body 272 and includes a gas distribution faceplate 240, often referred to as a showerhead, and a gas-feed cover plate 246, or temperature control plate, disposed on the showerhead 240 and in thermal communication therewith. An annular flange 247, (shown in FIG. 2) which is an integral component of the showerhead 240, is disposed on an isolator 264 to support the gas delivery assembly 231. A plurality of holes 242 are formed in the showerhead 240 and are adapted to accommodate gas flow therethrough into the process region 256. The gas is provided to the showerhead 240 by a central gas inlet 244 formed in the gas-feed cover plate 246. The gas-feed cover plate 246 also includes a multi-turn cooling/heating channel 233 to accommodate the flow of water or other fluid therethrough during processing in order to maintain the gas delivery assembly 231 at a desired temperature. The gas delivery assembly 231 may be cooled or heated depending on the particular chemicals being delivered through the central gas inlet 244.

In operation, the temperature controlled gas delivery assembly 231 is intended to contribute to uniform deposition and prevents gas decomposition, deposition, or condensation within the gas distribution system upstream from the process zone. In addition to assisting in gas delivery into the chamber 230, the showerhead 240 also acts as an electrode. During processing, a power source 294 supplies power to the showerhead 240 to facilitate the generation of a plasma. The power source 294 may be DC or RF.

In operation, a substrate 236 is positioned on the pedestal 232 through cooperation of a robot (not shown) and the lift pins 238. The pedestal 232 then raises the substrate 236 into close opposition to the showerhead 240. Process gas is then injected into the chamber 230 through the central gas inlet 244 in the gas-feed cover plate 246 to the back of the showerhead 240. The process gas then passes through the holes 242 and into the processing region 256 and towards the substrate 236, as indicated by the arrows. Upon reaching the substrate 236, the process gases react with the upper surface thereof. Subsequently, the process gas byproducts flow radially outwardly across the edge of the substrate 236, into a pumping channel 260 and are then exhausted from the chamber 230 by a vacuum system 282.

An exemplary processing regime for CVD deposition of tantalum or tantalum nitride barrier or liner layer on a 200 mm substrate in a chemical vapor deposition chamber as shown in FIG. 3 is as follows. Generally, depositing the layer includes introducing a processing gas of a metal organic precursor and a carrier gas into a processing chamber at a flow rate of between about 5 sccm and 500 sccm each for a 200 mm substrate and maintaining a chamber pressure of between about 100 milliTorr and about 20 Torr. If a reactant processing gas, such as ammonia, is being used to deposit a nitride layer, the reactant processing gas metal organic precursor are introduced into the chamber at a flow rate of between about 5 and about 500 sccm each. Preferably, the flow rate of the processing gases is maintained at a molar ratio of 1:1 of precursor to processing gas. The substrate is maintained at a temperature of between about 100° C. and about 450° C. during the deposition process.

The barrier or liner layer may also be deposited by a plasma enhanced reaction which additionally includes delivering a power density to the processing chamber between about 0.5 W/cm² and about 3.2 W/cm², or at a power level between about 200 Watts and about 1000 Watts for a 200 mm diameter substrate. The exemplary process for the deposition of tantalum and tantalum nitride layers from metal organic precursors is more fully described in co-pending U.S. patent application Ser. No. 09/505,638, entitled, “Chemical Vapor Deposition Of Barriers From Novel Precursors”, filed on Feb. 28, 2000, and in co-pending U.S. patent application Ser. No. 09/522,726, entitled, “MOCVD Approach To Deposit Tantalum Nitride Layers”, filed on Mar. 10, 2000, both of which are incorporated herein by reference to the extent not inconsistent with the aspects of the invention and claims described herein.

Deposition of the First Conductive Material of the Nucleation Layer.

The first conductive material of the nucleation layer of step 20 can be deposited by physical vapor deposition techniques, such as ionized metal plasma physical vapor deposition (IMP PVD) and collimated or long throw sputtering. Alternatively, the first conductive material is deposited by a chemical vapor deposition process known in the art in a CVD chamber, such as described in FIG. 3. The deposition of the nucleation layer will now be described in reference to an ionized metal plasma physical vapor deposition (IMP-PVD) chamber as shown in FIG. 2 and described above.

An exemplary process regime for the IMP deposition of a copper nucleation layer on a 200 mm substrate in an ion metal plasma (IMP) chamber is as follows. A substrate is positioned on a substrate support in the IMP-PVD having a target including a copper material. A noble gas, such as helium or argon, is introduced into the chamber at a rate sufficient to produce a chamber pressure between about 5 milliTorr and about 100 milliTorr. A chamber pressure between about 20 milliTorr and about 50 milliTorr is preferably used during the deposition process.

A plasma of the processing gases is generated and maintained by delivering a power density between about 0.5 W/cm² and about 77 W/cm², or a power level of between 500 watts and 5000 watts for a 200 mm substrate to the coil disposed in the processing chamber. A power level between about 1500W and about 2500W is preferably supplied to the coil.

A power density between about 0.6 W/cm² and about 19 W/cm², or a power level between about 200 watts (W) and about 6 kW for a 200 mm substrate, is delivered to the target to attract plasma ions to the target and causing sputtering. A power level between about 750 W and about 1500W is preferably supplied to the target to sputter the target. The sputtered material is then ionized through collisions with material in the plasma.

A power density less than about 2.0 W/cm², or a power level less than about 600 W for a 200 mm substrate, is delivered to the substrate support in order to attract ionized material produced in the plasma to the substrate. A power level between about 350 W and about 500 W is preferably delivered to the substrate support during the deposition process. The power supplied to the substrate support has a duty cycle between about 0% and about 100%, and preferably between about 50% and about 75%.

The substrate is maintained at a temperature between about −50° C. and about 150° C. A substrate temperature below about 50° C. is preferably used for processing during the deposition of the first conductive material of the nucleation layer. In one embodiment, the nucleation layer is deposited to a layer thickness between about 100 Å and about 2000 Å.

Alternatively, the target may further include a doping material selected from a group of phosphorus, boron, indium, tin, beryllium or combinations thereof. The percentage by weight of the doping material is between about 0.01% and about 15%. A doping percentage of between about 0.01% and about 0.5% is preferably used in depositing the nucleation layer. An exemplary apparatus and processing regime for depositing a doped material, such as copper, from a doped target in an IMP-PVD process is described in co-pending U.S. patent application Ser. No. 09/406,325, entitled “Method And Apparatus Of Forming A Sputtered Doped Seed Layer”, filed on Sep. 27, 1999, and incorporated by reference to the extent not inconsistent with the invention.

The doping material of the nucleation layer is believed to reduce surface diffusivity of the sputtered conductive material, such as copper, as the sputtered material is deposited. Less agglomeration occurs with the doping and the sputtered conductive layer is deposited more conformally with less voids. For a subsequent process, such as electroplating, which is affected by the integrity of an underlying nucleation layer, the doped layer yields a more uniform subsequent layer deposited thereon. Phosphorus and other doping materials act as deoxidants, which are believed to reduce oxidation of the deposited material. A lower level of oxidation reduces the resistance of both the target material and the deposited layer of the target material. The phosphorus is also believed to harden the target and the deposited layer. The phosphorus is also believed to lower the melting temperature of the copper, so that surface mobility, recrystallization, and planarization can occur at lower temperatures.

Alternatively, the first conductive material of the nucleation layer may be deposited by a CVD process in a chemical vapor deposition chamber, such as the process and apparatus described in co-pending U.S. patent application Ser. No. 08/792,292, entitled “Low Temperature Integrated Via and Trench Fill Process and Apparatus,” filed on Jan. 31, 1997, and incorporated by reference to the extent not inconsistent with the aspects of the invention and claims described herein.

Deposition of the Second Conductive Material, or Patching Layer.

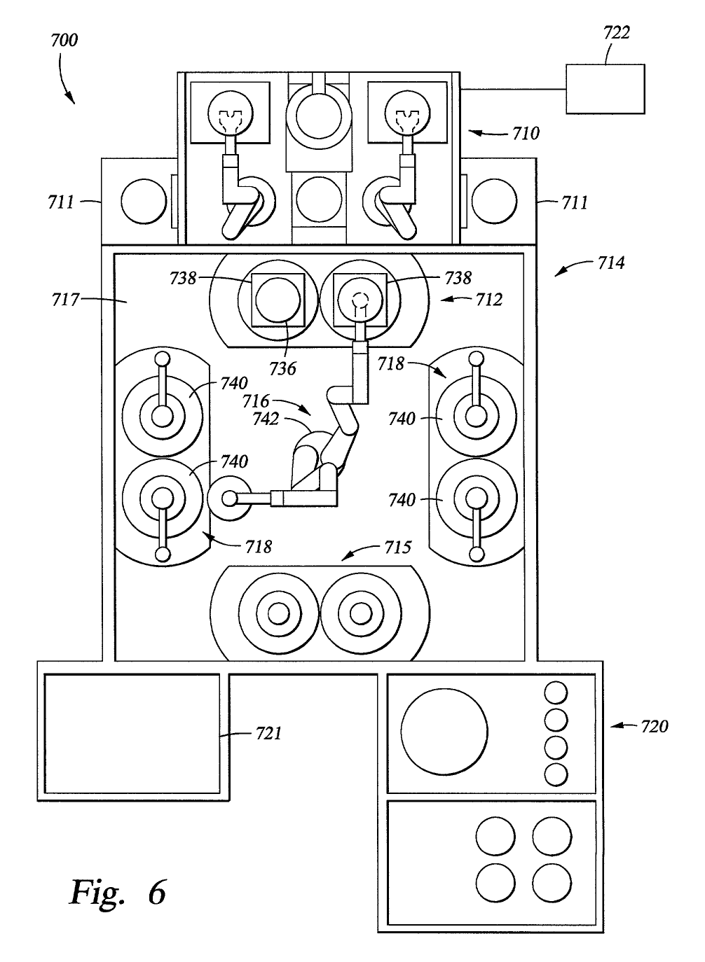

The substrate may then be transferred to an apparatus or system for performing the electrochemical deposition processes described herein. FIG. 6 is a schematic top view of one embodiment of an exemplary electroplating system platform 700 having the capacity to perform in-situ electroless deposition of a material and electroplating processes described herein. The exemplary electroplating system platform 700 having electrochemical deposition cells for carrying out the electroless and electroplating processes described herein is more fully described in co-pending U.S. patent application Ser. No. 09/350,877, entitled “In-Situ Electroless Copper Seed Layer Enhancement in An Electroplating System”, filed on Jul. 9, 1999, which is incorporated herein by reference to the extent not inconsistent with this invention.

The electroplating system platform 700 generally includes a loading station 710, a thermal anneal chamber 711, a mainframe 714, and an electrolyte replenishing system 720. The mainframe 714 generally includes a mainframe transfer station 716, a spin-rinse dry (SRD) station 712 including one or more SRD modules 736 and one or more substrate pass-through cassettes 738, a plurality of processing stations 718 for electroplating conductive materials, such as the copper nucleation layer or metal fill layer, a nucleation layer enhancement station 715 for depositing an electroless patching layer, and a mainframe transfer robot 742 disposed centrally to provide substrate transfer between various stations on the mainframe. Preferably, the electroplating system platform 700, including the mainframe 714, is enclosed in a clean environment using panels such as Plexiglas panels. The mainframe 714 includes a base 717 having cut-outs to support various stations used to complete the electrochemical deposition processes of the invention. Each processing station 718 includes one or more processing cells 740. An electrolyte replenishing system 720 is positioned adjacent the mainframe 714 and connected to the process cells 740 individually to circulate electrolyte used for the electroplating process. The electroplating system platform 700 also includes a power supply station 721 for providing electrical power to the system and a control system 722, typically including a programmable microprocessor.

The deposition of the second conductive material of the patching layer of step 30 will now be described in reference to electroless deposition process using processing equipment, such as the Electra Cum™ ECP platform commercially available from Applied Materials, Inc., of Santa Clara, Calif. The Electra Cu™ ECP platform preferably includes an integrated processing chamber capable of depositing a conductive material by an electroless process as described below. Electroless deposition is broadly defined herein as deposition of a conductive material generally provided as charged ions in a bath over a catalytically active surface to deposit the conductive material by chemical reduction in the absence of an external electric current.

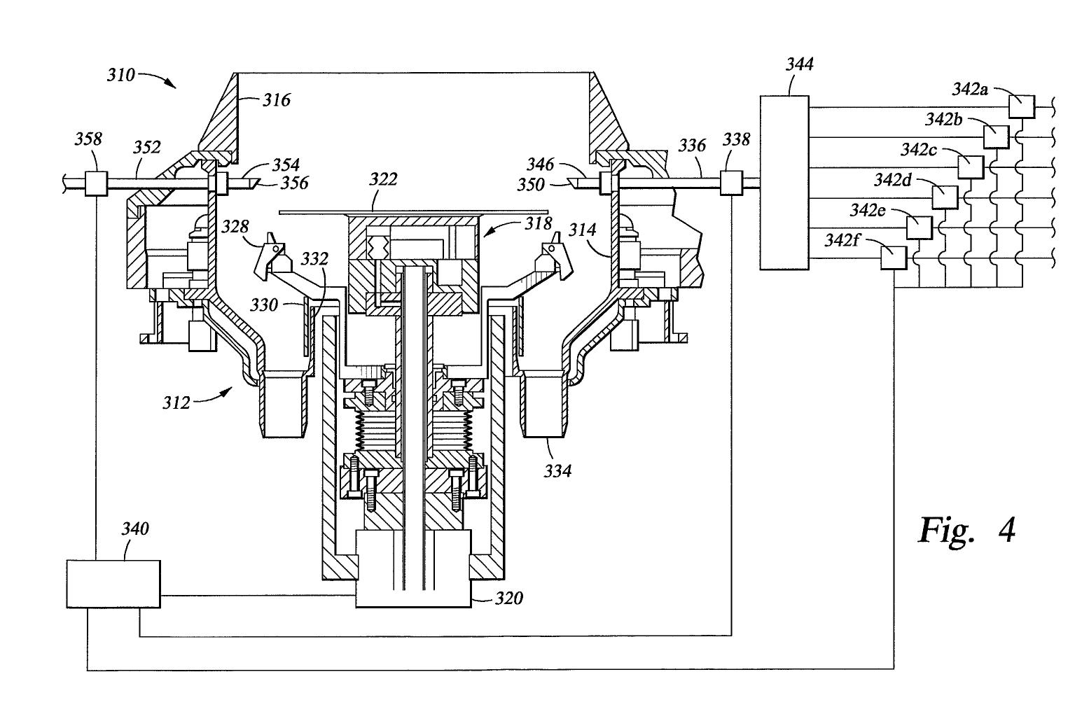

FIG. 4 is a schematic perspective view of one embodiment of an electroless deposition processing (EDP) cell 310 for depositing conductive materials for a patching layer as described herein. The EDP cell 310 includes a bottom 312, a sidewall 314, and an angularly disposed upper shield 316 attached to the sidewall 314 and open in the middle of the shield. A pedestal 318 is generally disposed in a central location of the cell 310 and includes a pedestal actuator 320. The pedestal actuator 320 rotates the pedestal 318 to spin a substrate 322 mounted thereon between about 10 and about 2000 RPMs. The pedestal can be heated so that the substrate temperature is between about 15° C. and about 100° C. In addition, the pedestal 318 can lower the substrate 322 to a vertical position aligned with a plurality of clamps 328 which engage the substrate 322 preferably on an edge of the substrate. The pedestal 318 also includes a downwardly disposed annular shield 330 of greater diameter than a corresponding upwardly disposed annular shield 332 coupled to the bottom of the cell 310 to protect the pedestal 318 and associated components from the fluids in the cell 310.

A first conduit 336, through which an electroless deposition fluid flows, is coupled to the cell 310. An electroless deposition fluid valve 338 controls the flow of the electroless deposition fluid. An electroless deposition fluid container 344 is connected to the valve 338 that can be controlled with a controller 340. A series of valves 342a-f are connected to various chemical sources (not shown), where the valves 342a-f can be separately controlled with the controller 340. The first conduit 336 connects to an first fluid inlet 346 disposed above the substrate 322 when the substrate is disposed in a lowered position. A first nozzle 350 is connected to the end of the inlet 346 and is directed toward the pedestal 318. The fluid(s) is generally delivered in a spray pattern, which may be varied depending on the particular nozzle spray pattern desired and may include a fan, jet, conical, and other patterns.

Similar to the first conduit and related elements, a second conduit 352 is disposed through the sidewall 314. The second conduit 352 provides a path for rinsing fluid, such as deionized water or alcohol that is used to rinse the substrate 322 after the electroless deposition. A second inlet 354 is connected to the second conduit 352 and a second nozzle 356 is connected to the second inlet 354. A second valve 358 is connected to the second conduit 352 and preferably controls the rinsing fluid timing and flow. The second conduit can also be coupled to a source of low concentration of acid or other fluids and a valve for controlling the fluid. The substrate can thus be transferred for subsequent processing such as electroplating in a “wet” state to minimize oxidation and other contaminants. The ability to transfer in a wet state is further enhanced if the substrate is maintained in a face up position for a period of time subsequent to the electroless deposition process. The controller 340 preferably controls each valve and therefore each fluid timing and flow.

In operation, a robot (not shown) delivers the substrate 322 face up to the EDP cell 310 and deposit the substrate 322 on the pedestal 318 for processing. The substrate 322 already has a nucleation layer deposited thereon such as described above. The controller 340 actuates the valves 342a-f to provide chemicals into the electroless fluid container 344, the chemicals are mixed, and the controller actuates the electroless deposition fluid valve 338 to open and allow a certain quantity of electroless deposition fluid into the first inlet 346 and through the first nozzle 350. Preferably, the pedestal 318 spins at a relatively slow speed of between about 10 and about 500 RPMs, allowing a quantity of fluid to uniformly coat the substrate 322. The spin direction can be reversed in an alternating fashion to assist in spreading the fluid evenly across the substrate. The electroless deposition fluid valve 338 is closed. The electroless deposition fluid auto-catalytically forms a layer over the predeposited nucleation layer and joins vacancies in the prior deposited layer to provide a more complete coating even in high aspect ratio features. Preferably, the electroless deposition process deposits between about 50 Å and about 500 Åfor most substrates.

The second valve 358 opens and a rinsing fluid flows through the second conduit 352 and is sprayed onto the substrate 322 through the second nozzle 356. Preferably, the pedestal 318 rotates at a faster speed of about 100 and about 500 RPMs as the remaining electroless deposition fluid is rinsed from the substrate 322 and is drained through an outlet and discarded. The substrate can be coated with an acid or other coating fluid. The pedestal 318 stops rotating and raises the substrate 322 to a position above the EDP cell 310. The robot retrieves the substrate for further processing in the electroplating cell.

Different electroless plating solutions (or electrolytes) may be used for depositing the desired conductive materials, using process conditions that are known in the art. For example, the patching layer of a second conductive material may be nickel (Ni) or tin (Sn), and doped derivatives thereof. In one embodiment, an electroless plating solution includes a water-soluble salt containing a conductive material to be deposited, along with other components such as a reducing agent, complexing agent, or stabilizer, among others. Examples of a reducing agent include hypophosphorous acid, water soluble hypophosphites such as sodium or potassium hypophosphite, among others. A complexing agent may include, for example, carboxylic acids such as malic acid, citric acid, or sodium salts of carboxylic acids, and others that are known in the art.

In one embodiment, an electroless nickel plating process includes the addition of a stabilizer such as water-soluble lead salts, e.g., lead acetate, to the electroless plating solution. For example, nickel and tin may be deposited from their respective sulfide, sulfate or chloride salts, and many other water-soluble salts containing the desired metallic ions can also be used in the electroless plating solution. Exemplary solutions and conditions for electroless plating nickel and tin may be found, for example, in Uchida et al., U.S. Pat. No. 5,910,340, issued on Jun. 8, 1999, and in Uchida et al., U.S. Pat. No. 5,248,527, issued on Sep. 28, 1993, both of which are incorporated herein by reference to the extent not inconsistent with this invention.

Depending on the specific metals or alloys to be deposited, the concentrations and compositions of the electroless plating solutions to be used in embodiments of the invention may be adjusted as appropriate, using suitable parameter ranges known in the art. As an illustrative embodiment, nickel may be plated from an acidic nickel sulphate solution using sodium hypophosphite as a reducing agent. The solution may include about 87 g/l NiSO₄4H₂O, 24 g/l Na₂H₂PO₂H₂O, 30 g/l CH₃COONa3H₂O, 4.1 C₃H₄(OH)(COOH)₃H₂O, 2 g/l NaO₂C₃H₄COONa6H₂O, and 0.0015 g/l Pb(CH₃COO)₂3H₂O.

In the case of tin (Sn) electroless deposition, a solution of a tin salt, thiourea and an acid may be used. Such a solution may include, for example, about 45 g/l of thiourea and 5 g/l of stannous chloride, SnCI₂2H₂O, and sulfuric acid. The sulfuric acid concentration may vary between about 1 and about 100 g/l. The use of these solutions for the electroless plating of Ni and Sn on copper surfaces have been disclosed by Lin et al., in “Manufacturing of Cu/Electroless Nickel/Sn-Pb Flip Chip Solder Bumps”, IEEE Trans. Adv. Packaging, vol. 22, pp.575-579 (November 1999), and by Sullivan et al., U.S. Pat. No. 2,369,620, issued on Feb. 13, 1945, both of which are incorporated herein by reference to the extent not inconsistent with this invention. Typically, electroless deposition is performed a temperature between about 10° C. and about 100° C.

The electroless deposition can be performed by either spraying the electroless plating solution onto the surface of the substrate, or by immersing the substrate in a bath containing the electroless plating solution. In one embodiment, Ni and Sn may be deposited from solutions including the respective sulfate or chloride salts. Many other salts that are known in the art may also be used. For example, Ronamerse 407—a plating solution available from LeaRonal of New York, is also suitable for depositing Sn on copper features. In one embodiment, electroless deposition can be achieved in less than about 30 seconds at room temperature by immersing a wafer containing copper features in a bath containing the Ronamerse 407 solution at about 50% dilution with water.

According to one aspect of the invention, the nucleation layer can act as a catalyst for electroless deposition. By using an appropriate reducing agent in the electroless plating solution (e.g., one in which a conductive materials, such as copper, can catalyze a reduction reaction involving the reducing agent), the patching layer can be formed selectively on one or more features of the wafer substrate. For example, a hypophosphite is a suitable reducing agent for use in electroless Ni deposition. Furthermore, depending on the material used for the conductive barrier layer, it is also possible to have electroless deposition on the conductive barrier layer.

Depending on the specific application and process needs, the deposition time may be adjusted to produce a patching layer having any desired thickness. Typically, the patching layer is deposited to a thickness of less than about 1000 Å. A thickness between about 50 Å and about 500 Å of the electroless patching layer is preferably deposited. In general, a relatively thin patching layer is preferred in order to avoid any excessive current passing through this patching layer during device operation. A deposition time of less than about 30 seconds, or a few seconds, has been observed to be sufficient to provide a continuous patching layer. Depending on the desired thickness or process throughput, the deposition time can be adjusted accordingly. For example, a deposition time of about 5 minutes may be used without significant impact on the process throughput.

After, the electroless layer has been deposited, the substrate may be rinsed prior to further processing. In one embodiment, the electroless layer is processed in a spin-rinse dry (SRD) station, such as those commercially available from Applied Materials, Inc. of Santa Clara, Calif. The SRD station is more fully described in co-pending U.S. patent application Ser. No. 09/350,877, entitled “In-Situ Electroless Copper Seed Layer Enhancement in An Electroplating System”, filed on Jul. 9, 1999, which is incorporated herein by reference to the extent not inconsistent with this invention.

The invention contemplates the use of other materials used as the second conductive material in the electroless deposition process. For example, copper is contemplated for use in a copper metallization scheme as described herein, where the first and third conducting materials include copper. In another example, a copper may also be used as the second conducting material of the electroless layer when nickel is used as the first conducting material. Doper nickel or copper, such as with phosphorus, boron, indium, tin, beryllium, and combinations thereof, may also be used as the second conductive material in the processes described herein. An exemplary electroless copper deposition chemistry and apparatus is more fully described in co-pending U.S. patent application Ser. No. 09/350,877, entitled “In-Situ Electroless Copper Seed Layer Enhancement in An Electroplating System”, filed on Jul. 9, 1999, which is incorporated herein by reference to the extent not inconsistent with this invention.

It is contemplated that the electroless deposition step improves the properties of the nucleation layer surface in one or more aspects. It has been observed that the adhesion between the nucleation layer and subsequently deposited conductive materials are enhanced. Furthermore, the patching layer of nickel or tin may serve as a barrier layer and reduce electromigration of subsequently deposited materials, such as copper, or undesirable interlayer diffusion between the substrate and subsequently deposited materials.

It is also contemplated that the electroless deposition of the patching layer fills defects and discontinuities in the nucleation layer to complete the formation of a conformal nucleation layer. A conformal nucleation layer allows subsequent processing, such as electroplating which can be affected by the integrity of the nucleation layer, to fill the remainder of the features without substantial voids in the deposited material. It is also contemplated that the layer uniformity also enhances the adhesion between the layers and further results in less void formations and discontinuities in the electroplated layer.

It is further contemplated that the patching layer and doping materials provide for increased layer evenness from increased current distribution, reduced layer agglomeration, improved electromigration properties, better grain growth control of the nucleation layer and subsequently deposited layers, and minimal void formation in high aspect ratio features. The doping materials of the patching layer improve the deposition of the conductive metal layers by reducing the surface diffusivity, or surface tension, one of the main causes of agglomeration, of conductive material during deposition.

Additionally, it is contemplated that the lower surface tension of the layer, lowers the surface mobility of the conductive metal layer which results in layer hardening which enhances the layer's resistance to electromigration of atoms in response to the high current density applied to the layer. Additionally, the doping materials may also be deoxidizing agents for conductive materials, such as copper, which reduces oxidation in the process. Oxidation can create a particle problem and can also contribute to layer agglomeration by forming oxides on the surface of the substrate.

Deposition of the Third Conductive Layer by Electroplating.

The deposition of the third conductive material by electroplating of step 40 will now be described in reference to electroplating deposition process using processing equipment, such as the Electra Cu™ ECP platform and an integrated processing chamber capable of depositing a conductive material by an electroplating process as described below. Electroplating is defined broadly herein as the deposition of a layer of conductive material on a substrate by passing an electric current between an anode and a cathode in an electrochemical bath containing ions of the conductive material.

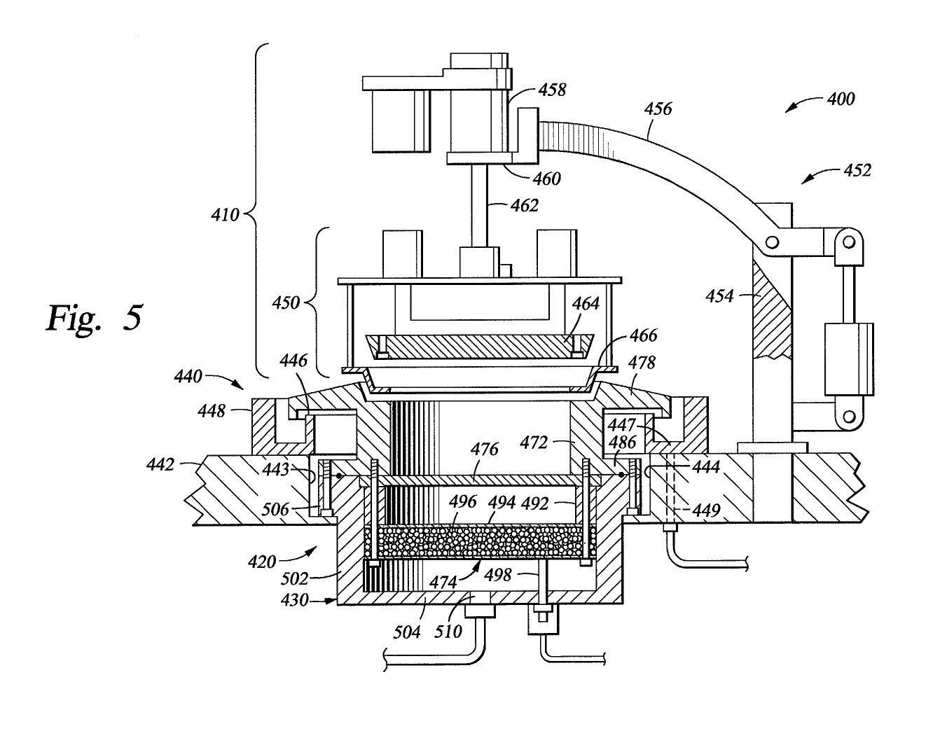

FIG. 5, is a cross sectional view of one embodiment of an electroplating process cell 400 that can be used to deposit the third conductive material or metal fill layer. The processing cell 400 generally includes a head assembly 410, a process kit 420 and an electrolyte collector 440. Preferably, the electrolyte collector 440 is secured onto the body 442 over an opening 443 that defines the location for placement of the process kit 420. The electrolyte collector 440 includes an inner wall 446, an outer wall 448 and a bottom 447 connecting the walls. An electrolyte outlet 449 is disposed through the bottom 447 of the electrolyte collector 440 and connected to the electrolyte replenishing system (not shown).

The head assembly 410 is mounted onto a head assembly frame 452. The head assembly frame 452 includes a mounting post 454 and a cantilever arm 456. The mounting post 454 is mounted onto the body 442, and the cantilever arm 456 extends laterally from an upper portion of the mounting post 454. Preferably, the mounting post 454 provides rotational movement with respect to a vertical axis along the mounting post to allow rotation of the head assembly 410.

The head assembly 410 generally includes a substrate holder assembly 450 and a substrate assembly actuator 458. A substrate assembly actuator 458 is mounted onto a mounting plate 460, and includes a head assembly shaft 462 extending downwardly through the mounting plate 460. The lower end of the head assembly shaft 462 is connected to the substrate holder assembly 450 to position the substrate holder assembly 450 in a processing position and in a substrate loading position. The substrate holder assembly 450 generally includes a substrate holder 464 and a cathode contact ring 466.

Referring back to FIG. 5, a cross sectional view of an electroplating process cell 400, the substrate holder assembly 450 is positioned above the process kit 420. The process kit 420 generally includes a bowl 430, a container body 472, an anode assembly 474 and a filter 476. The container body 472 is preferably a cylindrical body included of an electrically insulative material, such as ceramics, plastics, Plexiglas (acrylic), lexane, PVC, CPVC, and PVDF or a metal, such as stainless steel, nickel and titanium, which is coated with an insulating layer, such as Teflon, PVDF, plastic, rubber and other combinations of materials that do not dissolve in the electrolyte and can be electrically insulated from the electrodes (i.e., the anode and cathode of the electroplating system). The container body 472 is preferably sized and adapted to conform to the substrate plating surface and the shape of the of a substrate being processed through the system, typically circular or rectangular in shape.

An upper portion of the container body 472 extends radially outwardly to form an annular weir 478. The weir 478 extends over the inner wall 446 of the electrolyte collector 440 and allows the electrolyte to flow into the electrolyte collector 440. The upper surface of the weir 478 preferably matches the lower surface of the cathode contact ring 466. When a substrate is positioned in the processing position, the substrate plating surface is positioned above the cylindrical opening of the container body 472, and a gap for electrolyte flow is formed between the lower surface of the cathode contact ring 466 and the upper surface of the weir 478.

A lower portion of the container body 472 extends radially outwardly to form a lower annular flange 486 for securing the container body 472 to the bowl 430. Preferably, the filter 476 is attached to and completely covers the lower opening of the container body 472, and the anode assembly 474 is disposed below the filter 476. Preferably, the filter 476 and the anode assembly 474 are fastened to a lower surface of the container body 472 using removable fasteners, such as screws and/or bolts. Alternatively, the filter 476 and the anode assembly 474 are removably secured to the bowl 430. The filter 476 preferably includes a ceramic diffuser that also serves to control the electrolyte flow pattern toward the substrate plating surface.

The anode assembly 474 preferably includes a consumable anode that serves as a metal source in the electrolyte. Alternatively, the anode assembly 474 includes a non-consumable anode, and the metal to be electroplated is supplied by an electrolyte from in an electrochemical bath. The anode assembly 474 is a self-enclosed module having a porous anode enclosure 494 preferably made of the same metal as the metal to be electroplated, such as copper. Alternatively, the anode enclosure 494 is made of porous materials, such as ceramics or polymeric membranes. A soluble metal 496, such as high purity copper for electrochemical deposition of copper, is disposed within the anode enclosure 494. The soluble metal 496 preferably includes metal particles, wires or a perforated sheet. The porous anode enclosure 494 also acts as a filter that keeps the particulates generated by the dissolving metal within the anode enclosure 494.

An anode electrode contact 498 is inserted through the anode enclosure 494 to provide electrical connection to the soluble metal 496 from a power supply. Preferably, the anode electrode contact 498 is made from a conductive material that is insoluble in the electrolyte, such as titanium, platinum and platinum-coated stainless steel. The anode electrode contact 498 extends through the bowl 430 and is connected to an electrical power supply.

The bowl 430 generally includes a cylindrical portion 502 and a bottom portion 504. An upper annular flange 506 extends radially outwardly from the top of the cylindrical portion 502. The upper annular flange 506 of the bowl 430 is fixedly connected with the lower annular flange 486 of the container body 472. The cylindrical portion 502 accommodates the anode assembly 474 and the filter 476. Preferably, the outer dimensions of the filter 476 and the anode assembly 474 are slightly smaller than the inner dimension of the cylindrical portion 502 to force a substantial portion of the electrolyte to flow through the anode assembly 474 first before flowing through the filter 476. The bottom portion 504 of the bowl 430 includes an electrolyte inlet 510 that connects to an electrolyte supply line from a electrolyte replenishing system. The electrolyte inlet 510 and the electrolyte supply line are connected by a releasable connector that facilitates easy removal and replacement of the process kit 420.

An exemplary electroplating chemistry for depositing a copper layer in a system containing a soluble anode is described in co-pending U.S. application Ser. No. 09/245,780, filed on Feb. 5, 1999, entitled, “Electrodeposition Chemistry For Improved Filling Of Apertures”, and is incorporated herein by reference to the extent not inconsistent with this invention. An exemplary electroplating method is also described in co-pending U.S. patent application Ser. No. 09/114,865, entitled “Electro Deposition Chemistry”, filed on Jul. 13, 1998, and is incorporated herein by reference to the extent not inconsistent with this invention.

Post Deposition Treatment of the Substrate.

After the aperture is filled, the substrate may be annealed to recrystallize the copper and remove void formation. After annealing the substrate, the substrate may be planarized by a chemical mechanical polishing (CMP), to define a conductive feature on the substrate of step 50.

It is contemplated that the annealing process may further diffuse any doping material from the patching layer into the nucleation layer and the conducting layer, thereby enhancing the electromigration resistance of the copper-filled aperture. The invention contemplates utilizing a variety of annealing processes having various parameters to treat the substrate, including such process as plasma annealing. The invention contemplates utilizing a variety of thermal anneal chamber designs, including hot plate designs and heat lamp designs, to enhance the electroplating results.

An example of a suitable anneal chamber is a rapid thermal anneal chamber, such as the RTP XEplus Centura® thermal processor available from Applied Materials, Inc., Santa Clara, Calif. In one embodiment, the annealing occurs between about 200° C. and about 400° C. for between about 15 seconds and about 1 minute in a rapid thermal anneal processor. An exemplary in-situ anneal chamber for the processes described herein is described in co-pending U.S. patent application Ser. No. 09/263,126, entitled, “Apparatus For Electro Chemical Deposition Of Copper Metallization With Capability Of In-Situ Thermal Annealing,” filed on Mar. 5, 1999, which is incorporated herein by reference to the extent not inconsistent with this invention.

An example of a suitable chemical-mechanical polishing apparatus is a Mirra Mesam™ CMP system, available commercially from Applied Materials, Inc., of Santa Clara, Calif. A description of the Mirra CMP system has been disclosed in commonly-assigned U.S. provisional patent application, entitled “Method and Apparatus For Transferring Semiconductor Wafers Using An Input Module,” Ser. No. 60/139,222, filed on Jun. 15, 1999, which is incorporated herein by reference.

An Example of the Deposition Processes

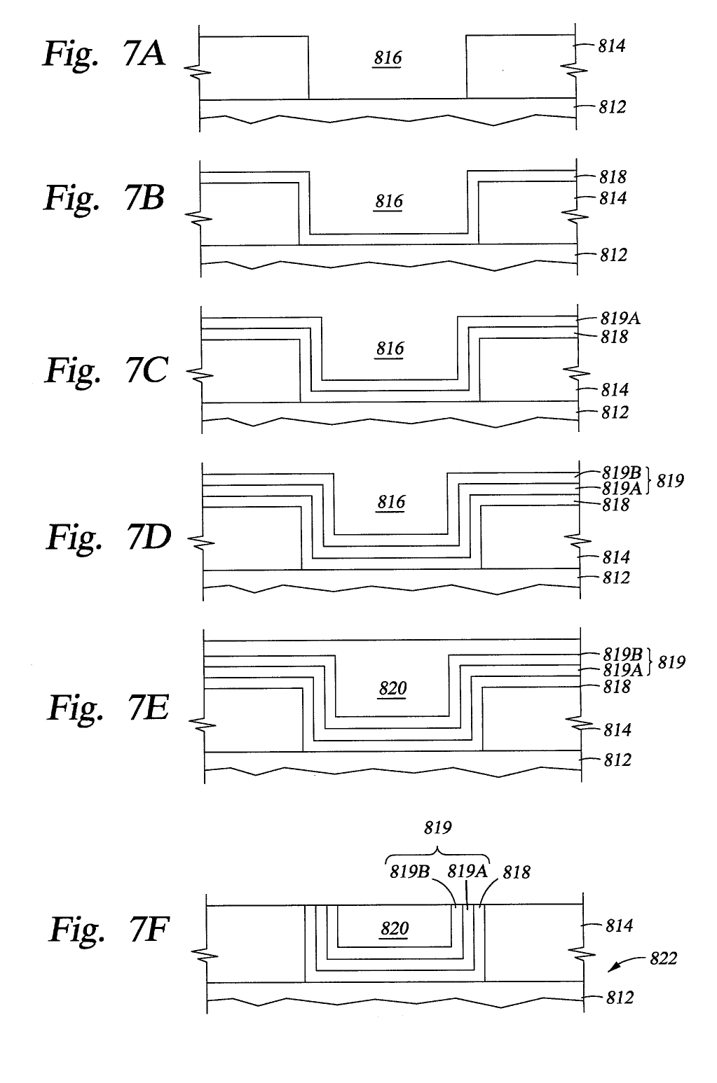

FIGS. 7A-7F further illustrate one embodiment of the deposition methods described herein. Referring to FIGS. 7A-7F, generally, an aperture 816 is first formed in a dielectric layer 814 on the substrate 812. A barrier (or liner layer) 818 is deposited on then conformally deposited on the field of the substrate and in apertures 816 formed therein. A nucleation layer 819A, such as copper, is then deposited on the barrier layer 818 and a patching layer 819B of a second conductive material, such as nickel, is deposited on the nucleation layer 819A by an electroless deposition process. A conductive layer 820 of a third conductive material, such as copper, is electroplated on the patching layer 819B to fill the feature. The substrate 812 may further be annealed and then planarized using a chemical mechanical polishing process. While the following process describe the use of a barrier layer, the invention contemplates using a liner layer in conjunction with the barrier layer, or using a material that may perform as both a liner layer or barrier layer material.

Referring to FIG. 7A, the aperture 816 is formed by depositing and pattern etching a dielectric layer 814 on the substrate 812 to form the desired aspect of the aperture 816, such as a via, contact, trench or line. The substrate 812, typically including a doped silicon substrate or a first or subsequent electrically conductive layer formed on a silicon based substrate, is introduced into a processing chamber and a dielectric layer 814 is deposited thereon. The dielectric layer 814 can be a pre-metal dielectric layer deposited over the substrate or an inter-level dielectric layer.

The dielectric layer 814 may be of any dielectric material, whether presently known or yet to be discovered, and is within the scope of the invention known in the art. The dielectric layer 814 may be deposited by conventional methods known in the art, such as by chemical vapor deposition (CVD) techniques. The term “aperture” is broadly defined in accordance with its customary usage in the semi-conductor industry, and is more particularly defined herein as a substrate structure formed in the substrate material or materials deposited on the substrate, and includes, but is not limited to, such substrate structures as vias, contacts, interconnects, and dual damascenes.

Referring to FIG. 7B, the substrate 812 may be transferred to a processing chamber to deposit a barrier layer 818 on the dielectric layer prior to depositing the nucleation later 819A. The barrier layer may be deposited prior to the nucleation layer 819A, the patching layer 819B, and the conductive layer 820 to promote adhesion of the nucleation layer to the underlying material and to prevent or inhibit diffusion of layers 81 9A, 81 9B, and 820 into the underlying substrate 812 or dielectric layers 814. The barrier materials are typically tantalum (Ta), tantalum nitride (TaN), or combinations thereof, for copper layers, copper alloy layers, or doped copper layers, which may be deposited individually or sequentially. The barrier layer is deposited using an ionized metal plasma physical vapor deposition (IMP PVD) process described above.

The nucleation layer 819A of a first conductive material is deposited on the barrier layer 818 to nucleate subsequently deposited conductive metal layers, such as the conductive layer 820 as shown in FIG. 7C. The nucleation layer 819A includes copper. Alternatively, the first conductive layer 819A includes copper doped with a material such as boron or phosphorus. The nucleation layer 81 9A is deposited using an ionized metal plasma physical vapor deposition (IMP-PVD) technique.

Referring to FIG. 7D, the substrate 812 is transferred to an electroless deposition processing (EDP) cell where a patching layer 819B is deposited over the nucleation layer 819A using an electroless deposition process. The patching layer 819B includes nickel. The patching layer 819B is preferably doped with a phosphorus or boron doping material when using a copper nucleation layer 819A to improve electromigration performance and to promote the deposition of uniform layers and reduce the formation of deposition defects from layer agglomeration. The electroless patching layer 819 is deposited to thickness between about 50 Å and about 500 Å. A thickness between about 50 Å and about 250 Å is preferably used in depositing the electroless patching layer 819.

In one embodiment of the invention, the deposited nucleation layer 819A and patching layer 819B form a nucleation layer 819 to promote the nucleation and deposition of the subsequent conductive layer 820 to form a feature with minimal void formation.

Referring to FIG. 7E, a layer of copper material 820 is deposited on the patching layer 819B by an electroplating process to fill the aperture 816. Following deposition of the conductive layers, the substrate may be treated to an anneal process to minimize void formation and recrystallize the deposited materials. The annealing process may further diffuse any doping material from the patching layer 819B into the nucleation layer 819A and the conductive layer 820, thereby enhancing the electromigration resistance of the filled aperture 816.

Referring to FIG. 7F, the filled aperture 816 may be further processed by planarizing the top portion of the aperture 816 to form feature 822, preferably by chemical mechanical polishing (CMP). During the planarization process, portions of the dielectric layer 814, the barrier layer 818, the copper nucleation layer 819A, the nickel patching layer 819B, and the copper layer 820 are removed from the top of the structure leaving a fully planar surface. Other subsequent processing can include annealing if desired, additional deposition of layers, etching, and other processes known to IC manufacturing.

While the foregoing is directed to the one or more embodiments of the invention, other and further embodiments of the invention may be devised without departing from the basic scope thereof, and the scope thereof is determined by the claims that follow including their equivalents.

What is claimed is:

1. A method for processing a substrate, comprising:
depositing a barrier layer on a substrate; then
depositing a first conductive material on the barrier layer; and
depositing a second conductive material on the first conductive material by an electroless deposition process to fill discontinuities formed in the first conductive material.

2. The method of claim 1, wherein the barrier layer is deposited by a physical vapor deposition process or a chemical vapor deposition process.

3. The method of claim 1, wherein the first conductive material is deposited by a physical vapor deposition process or a chemical vapor deposition process.

4. The method of claim 1, further comprising depositing a third conductive material on the second conductive material by an electroplating process.

5. The method of claim 4, wherein the barrier layer is deposited by physical vapor deposition, the nucleation layer is deposited by physical vapor deposition and the second conductive material is deposited by an electroless deposition process.

6. The method of claim 1, further comprising rinsing the substrate after the electroless deposition.

7. The method of claim 1, further comprising annealing the substrate after electroplating the third conductive material.

8. The method of claim 5, wherein the nucleation layer comprises copper, the second conductive material comprises nickel deposited by an electroless deposition process, the substrate is rinsed after the electroless deposition process, the third conductive material comprises copper, and the substrate is annealed after electroplating the third conductive material.

9. The method of claim 1, wherein the first conductive material is selected from the group of copper, nickel, tungsten, and combinations thereof.

10. The method of claim 9, wherein the first conductive material further comprises a doping material selected from the group of phosphorus, boron, indium, tin, beryllium, and combinations thereof.

11. The method of claim 1, wherein the second conductive material is selected from the group of nickel, tin, and combinations thereof.

12. The method of claim 11, wherein the second conductive material further comprises a doping material selected from the group of phosphorus, boron, indium, tin, beryllium, and combinations thereof.

13. The method of claim 4, wherein the third conductive material is selected from the group of copper, doped copper, nickel, doped nickel, and combinations thereof.

14. The method of claim 4, wherein the nucleation layer comprises copper, the second conductive material comprises nickel, and the third conductive material comprises copper.

15. A method for processing a substrate, comprising:
depositing a barrier layer on the substrate;
depositing a seed layer of a first conductive material on the barrier layer by a physical vapor deposition process or a chemical vapor deposition process;
exposing the substrate to an electroless deposition process to deposit a second conductive material selected from the group of nickel, tin, and combinations thereof, on the seed layer to fill discontinuities formed in the seed layer; and
depositing a third conductive material on the second conductive material by an electroplating process.

16. The method of claim 15, further comprising rinsing the substrate after the electroless deposition.

17. The method of claim 15, further comprising annealing the substrate after electroplating the third conductive material.

18. The method of claim 15, wherein the barrier layer is deposited by a physical vapor deposition process or a chemical vapor deposition process.

19. The method of claim 15, wherein the barrier layer is deposited by physical vapor deposition, the seed layer comprises copper deposited by physical vapor deposition, the second conductive material comprises nickel deposited by an electroless deposition process, the substrate is rinsed after the electroless deposition process, and the substrate is annealed after the third conductive material is deposited by an electroplating process.

20. The method of claim 15, wherein the first conductive material comprises a conductive material selected from the group of copper, nickel, tungsten, and combinations thereof.

21. The method of claim 20, wherein the first conductive material further comprises a doping material selected from the group of phosphorus, boron, indium, tin, beryllium, and combinations thereof.

22. The method of claim 15, wherein the second conductive material further comprises a doping material selected from the group of phosphorus, boron, and combinations thereof.

23. The method of claim 15, wherein the third conductive material is selected from the group of copper, doped copper, nickel, doped nickel, and combinations thereof.

24. The method of claim 15, wherein the seed layer comprises copper, the second conductive material comprises nickel, and the third conductive material comprises copper.

25. A method for patching electroplating seed layer, comprising:
depositing a barrier layer on the substrate;
depositing a copper seed layer on the barrier layer by a physical vapor deposition process, wherein the copper seed layer is discontinuous;
depositing a nickel patching layer on the copper seed layer by an electroless deposition process;
depositing a copper layer on the nickel patching layer by an electroplating process; and
annealing the substrate after electroplating the third conductive material.

26. The method of claim 25, further comprising rinsing the substrate after the electroless deposition.

27. The method of claim 25, wherein the copper seed layer further comprises a doping material selected from the group of phosphorus, boron, indium, tin, beryllium, and combinations thereof.

28. The method of claim 25, wherein the nickel patching layer further comprises a doping material selected from the group of phosphorus, boron, and combinations thereof.

29. A method for depositing a conductive layer in a feature on a substrate, comprising:
depositing a first conductive layer in a feature on the substrate;
depositing a second conductive layer in the feature by an electroless deposition process; and
electroplating a third conductive layer in the feature to at least partially fill the feature.

30. The method of claim 29, wherein the first conductive layer is deposited by a physical vapor deposition process.

31. The method of claim 29, wherein the electroless deposition occurs in an electroless deposition process cell coupled to an electroplating platform.

32. The method of claim 29, further comprising rinsing the substrate after the electroless deposition.

33. The method of claim 29, further comprising depositing a quantity of electroless deposition fluid on the substrate and spinning the substrate to distribute the quantity at least partially across the surface of the substrate.

34. The method of claim 29, further comprising mixing components of the electroless deposition fluid in proximity to the substrate.

35. The method of claim 29, further comprising mixing components of the electroless deposition fluid in individual application quantities.
